(19) United States
(12) Patent Application Publication
(10) Pub. No.: US 2025/0080061 A1
(43) Pub. Date: Mar. 6, 2025

(54) SEMICONDUCTOR DEVICE, AMPLIFIER AND BIASING CIRCUIT

(71) Applicant: Realtek Semiconductor Corporation, Hsinchu (TW)

(72) Inventors: Kai-Yen CHANG, Hsinchu (TW); Hung-Yu TSAI, Hsinchu (TW)

(21) Appl. No.: 18/817,237

(22) Filed: Aug. 28, 2024

Related U.S. Application Data
(60) Provisional application No. 63/580,387, filed on Sep. 4, 2023.

(30) Foreign Application Priority Data
Jun. 4, 2024 (TW) 113120698

(51) Int. Cl. H03F 3/04

(52) U.S. Cl. CPC H03F 3/04

(57) ABSTRACT

The present disclosure provides a semiconductor device. The semiconductor device includes a first transistor and a second transistor. The first transistor is configured to conduct in a first enable period. The second transistor is configured to conduct in a second enable period. The first transistor and the second transistor are coupled in series. The first enable period includes a first delay period, the second enable period and a second delay period that are arranged sequentially.

### CROSS-REFERENCE TO RELATED APPLICATION

This application claims priority to U.S. Provisional Application Ser. No. 63/580,387 filed Sep. 4, 2023, and Taiwan Application Serial Number 113120698 filed Jun. 4, 2024, which are herein incorporated by reference in its entirety.

### BACKGROUND

### Field of Invention

This disclosure relates to semiconductor circuit technology, and in particular to a semiconductor device, an amplifier, and a biasing circuit that can prevent surges or overshoots.

### Description of Related Art

With the advancement of semiconductor process technology, the channel length and gate oxide layer thickness of transistors are continuously shrinking. Therefore, chips produced using advanced processes have the advantages of low power consumption, high component density, and high computing speed. However, a thinner oxide layer means a lower voltage withstand capability, so the transistor in the chip's input/output (I/O) circuits is often damaged due to voltage surges or current surge.

### SUMMARY

An embodiment of present disclosure relates to a semiconductor device. The semiconductor device includes a first transistor and a second transistor. The first transistor is configured to be conducted during a first enable period. The second transistor is configured to be conducted during a second enable period. The first transistor and the second transistor are coupled in series. The first enable period includes a first delay period, the second enable period and a second delay period arranged in sequence.

Another embodiment of present disclosure relates to an amplifier. The amplifier includes a first semiconductor device and a second semiconductor device. The second semiconductor device coupled to the first semiconductor device. The first semiconductor device and the second semiconductor device each include a first transistor, a second transistor and a third transistor. The first transistor is configured to be conducted during a first enable period. The second transistor is configured to be conducted during a second enable period. The third transistor is coupled between the first transistor and the second transistor. The first transistor is configured to receive an input signal, and the second transistor is configured to generate an output signal. The first enable period includes a first delay period, the second enable period and a second delay period arranged in sequence. The third transistor is conducted at least during the second enable period.

Another embodiment of present disclosure relates to a biasing circuit. The biasing circuit includes a semiconductor device, a first voltage generation circuit, a second voltage generation circuit and a third voltage generation circuit. The semiconductor device includes a first transistor, a second transistor and a third transistor. The third transistor is coupled between the first transistor and the second transistor. The first voltage generation circuit is configured to output a first switch signal to control the first transistor to be conducted in a first enable period. The second voltage generation circuit is configured to output a second switch signal to control the second transistor to be conducted in a second enable period. The third voltage generation circuit is configured to output a third switch signal to control the third transistor to be conducted at least during the second enable period. The third voltage generation circuit and the third transistor form an negative feedback. The first enable period includes a first delay period, the second enable period and a second delay period arranged in sequence.

In sum, one of the advantages of the semiconductor device, amplifier and biasing circuit mentioned above is that it can prevent surges or overshoots.

### BRIEF DESCRIPTION OF THE DRAWINGS

FIG. 1 is a schematic diagram of a semiconductor device according to an embodiment of this disclosure.

FIG. 2 is a schematic diagram of a signal waveform of a semiconductor device according to an embodiment of this disclosure.

FIG. 3A is a schematic diagram of a semiconductor device according to an embodiment of this disclosure.

FIG. 3B is a schematic diagram of a semiconductor device according to another embodiment of this disclosure.

FIG. 4 is a schematic diagram of a signal waveform of a semiconductor device according to an embodiment of this disclosure.

FIG. 5 is a schematic diagram of a signal waveform of a semiconductor device according to an embodiment of this disclosure.

FIG. 6 is a schematic diagram of a signal waveform of a semiconductor device according to an embodiment of this disclosure.

FIG. 7 is a schematic diagram of a semiconductor device according to an embodiment of this disclosure.

FIG. 8 is a schematic diagram of a signal waveform of a semiconductor device according to an embodiment of this disclosure.

FIG. 9 is a schematic diagram of an amplifier according to an embodiment of this disclosure.

FIG. 10 is a schematic diagram of a biasing circuit according to an embodiment of this disclosure.

### DETAILED DESCRIPTION

The embodiments are described in detail below with reference to the appended drawings to better understand the aspects of the present disclosure. However, the provided embodiments are not intended to limit the scope of the disclosure, and the description of the structural operation is not intended to limit the order in which they are performed. Any device that has been recombined by components and produces an equivalent function is within the scope covered by the disclosure.

The terms used in the entire specification and the scope of the patent application, unless otherwise specified, generally have the ordinary meaning of each term used in the field, the content disclosed herein, and the particular content.

Certain words are used in the specification and patent claims to refer to specific components. However, the person having ordinary skill in the art should understand that the same component may be referred to by different names. The specification and the claim scope do not use the difference in name as a way to distinguish components, but the difference in function of the components as the basis for distinction. The “include” mentioned in the specification and claim scope is an open-ended term, so it should be interpreted as “include but not limited to”. In addition, the terms “coupled” or “connected” as used herein may mean that two or more elements are directly in physical or electrical contact, or are indirectly in physical or electrical contact with each other. It can also mean that two or more elements interact with each other.

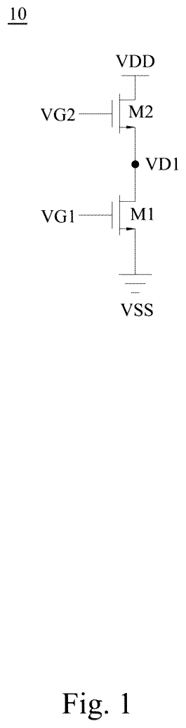

Referring to FIG. 1, FIG. 1 is a schematic diagram of a semiconductor device 10 according to an embodiment of this disclosure. The semiconductor device 10 includes a first transistor M1 and a second transistor M2. The first transistor M1 and the second transistor M2 are coupled in series between a power terminal VSS and a power terminal VDD, where the voltage of the power terminal VDD is higher than the voltage of the power terminal VSS. The first transistor M1 is controlled by a first switch signal VG1, and the second transistor M2 is controlled by a second switch signal VG2. In some embodiments, the first transistor M1 and the second transistor M2 may be implemented by N-type metal-oxide-semiconductor field-effect transistors (NMOSFET), that is, N-type transistors. In some embodiments in which the semiconductor device 10 is configured as an input-output (I/O) circuit, the semiconductor device 10 is a biasing circuit.

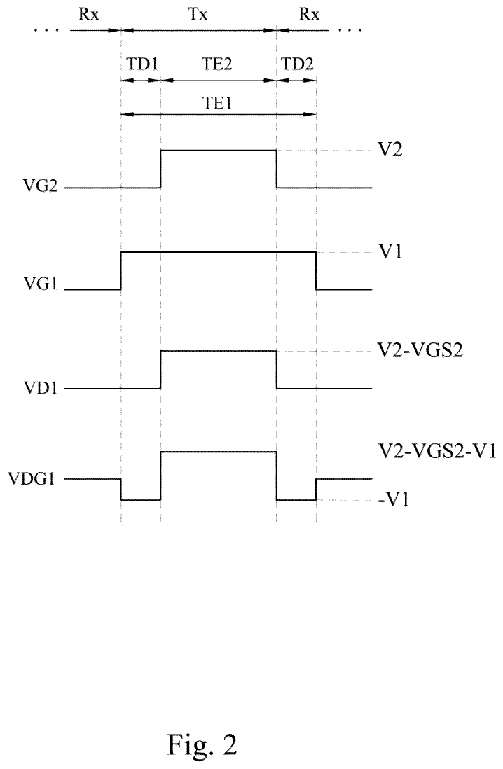

Referring to FIG. 1 and FIG. 2 at the same time, FIG. 2 is a schematic diagram of a signal waveform of the semiconductor device 10 according to an embodiment of this disclosure. FIG. 2 illustrates the time sequence relationship between the following multiple signals and multiple voltages: the first switch signal VG1, the second switch signal VG2, a drain voltage VD1 of the first transistor M1, a drain-gate voltage VDG1 of the first transistor M1 and a gate-source voltage VGS2 of the second transistor M2. The semiconductor device 10 may alternately operate in a receiving mode Rx and a transmitting mode Tx. Before switching from the receiving mode Rx to the transmitting mode Tx, the semiconductor device 10 does not output a signal, so the first switch signal VG1 and the second switch signal VG2 have a low voltage (e.g., ground voltage) to switch off the first transistor M1 and the second transistor M2.

When entering the transmitting mode Tx, the first switch signal VG1 switches to a first voltage V1 to conduct the first transistor M1, thereby placing the drain of the first transistor M1 in a low impedance state. The first switch signal VG1 may remain at the first voltage V1 during a first enable period TE1. In addition, after the first switch signal VG1 switches to the first voltage V1 and passes a first delay period TD1, the second switch signal VG2 switches to a second voltage V2 to be conducted the second transistor M2. Since when the second transistor M2 is conducted, the drain of the first transistor M1 is in a low impedance state in advance, the drain of the first transistor M1 may not generate voltage surge or overshoot due to charge accumulation.

After the second switch signal VG2 switches to the second voltage V2 and passes a second enable period TE2, the semiconductor device 10 finishes the transmitting mode Tx and enters the receiving mode Rx, and the second switch signal VG2 switches to the low voltage to switch off the second transistor M2. After the second switch signal VG2 switches to the low voltage and passes a second delay period TD2, the first switch signal VG1 switches to the low voltage to switch off the first transistor M1. Since when the first transistor M1 is switched off, the second transistor M2 has been switched off in advance, the drain of the first transistor M1 may not generate voltage surge or overshoot due to charge accumulation.

The first delay period TD1 and the second delay period TD2 may be the same or different. In some embodiments, the first delay period TD1 and the second delay period TD2 are each in the range of 50 to 200 nanoseconds (ns), but this disclosure is not limited to this time range. In some embodiments, the first delay period TD1 is longer than the second delay period TD2 to wait for a low-dropout regulator (LDO regulator), which is configured to supply power to the power terminal VDD, to enter a stable state, and the second delay period TD2 is shorter than the first delay period TD1 to stop the output of the semiconductor device 10 as soon as possible.

In summary, to prevent the semiconductor device 10 from being damaged due to voltage surge or overshoot, the first transistor M1 is configured to be conducted during the first enable period TE1, and the second transistor M2 is configured to be conducted during the second enable period TE2, wherein the first enable period TE1 includes the first delay period TD1, the second enable period TE2 and the second delay period TD2 arranged in sequence. Additionally, in some embodiments, the first voltage V1 is lower than a breakdown voltage of the first transistor M1, and the first voltage V1 is higher than a threshold voltage of the first transistor M1, therefore the absolute value of the drain-gate voltage VDG1 of the first transistor M1 remains lower than the absolute value of the breakdown voltage of the first transistor M1.

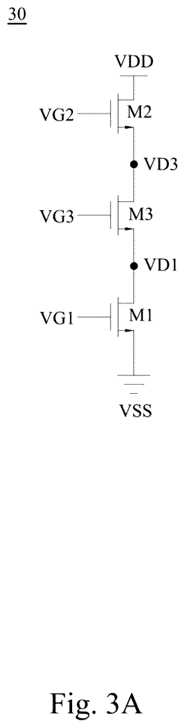

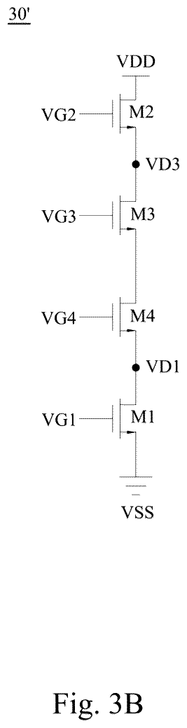

FIG. 3A is a schematic diagram of a semiconductor device 30 according to an embodiment of this disclosure. The semiconductor device 30 includes the first transistor M1, the second transistor M2, and a third transistor M3. The first transistor M1, the third transistor M3 and the second transistor M2 are coupled in series between the power terminal VSS and the power terminal VDD. That is, the third transistor M3 is coupled between the first transistor M1 and the second transistor M2. In some embodiments, the first transistor M1, the second transistor M2, and the third transistor M3 may be implemented by N-type transistors. The first transistor M1, the second transistor M2 and the third transistor M3 are respectively controlled by the first switch signal VG1, the second switch signal VG2 and a third switch signal VG3. Similar to the semiconductor device 10 in FIG. 1, in some embodiments, the semiconductor device 30 in FIG. 3A is a biasing circuit.

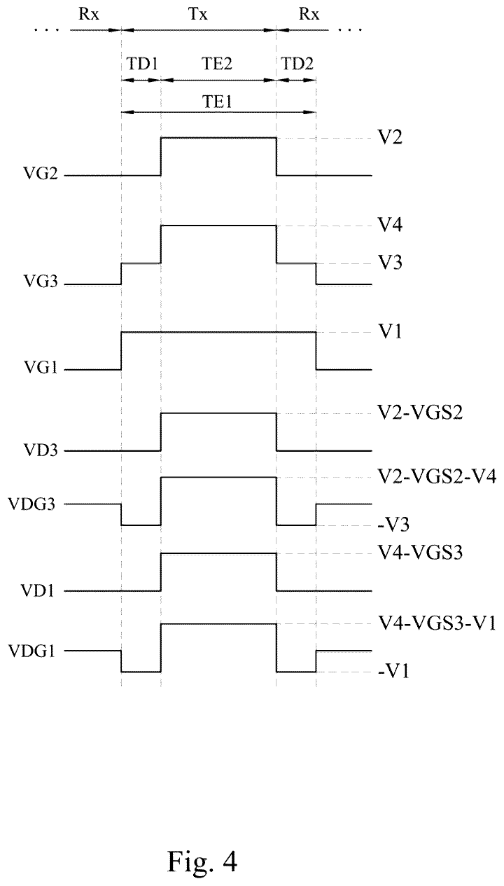

Referring to FIG. 3A and FIG. 4 at the same time, FIG. 4 is a schematic diagram of a signal waveform of the semiconductor device 30 according to an embodiment of this disclosure. FIG. 4 illustrates the time sequence relationship between the following multiple signals and multiple voltages: the first switch signal VG1, the second switch signal VG2, the third switch signal VG3, the drain voltage VD1 of the first transistor M1, the drain-gate voltage VDG1 of the first transistor M1, the gate-source voltage VGS2 of the second transistor M2, the drain voltage VD3 of the third transistor M3, a drain-gate voltage VDG3 of the third transistor M3 and a gate-source voltage VGS3 of the third transistor M3. The waveforms of the first switch signals VG1 and the second switch signal VG2 in FIG. 4 are similar to the content described above in connection with FIG. 2. For the sake of simplicity, they will not be repeated here.

Before switching from the receiving mode Rx to the transmitting mode Tx, the third switch signal VG3 has the low voltage to switch off the third transistor M3. When entering the transmitting mode Tx, the third switch signal VG3 switches to a third voltage V3 to be conducted the third transistor M3, therefore the drain of the first transistor M1 and the drain of the third transistor M3 are in a low impedance state. After the third switch signal VG3 switches to the third voltage V3 and passes the first delay period TD1, the third switch signal VG3 switches to a fourth voltage V4 and remains at the fourth voltage V4 during the second enable period TE2. In this way, even if the second transistor M2 is conducted early due to the offset of the component characteristics, since the drain of the first transistor M1 and the drain of the third transistor M3 are in a low impedance state in advance, the drain of the first transistor M1 and the drain of the third transistor M3 may not generate voltage surge or overshoot.

After the third switch signal VG3 switches to the fourth voltage V4 and passes the second enable period TE2, the third switch signal VG3 switches to the third voltage V3. The third switch signal VG3 remains at the third voltage V3 during the second delay period TD2, and then switches to the low voltage to switch off the third transistor M3. In this way, even if the second transistor M2 is delayed to be switched off due to the offset of the component characteristics, the drain of the first transistor M1 and the drain of the third transistor M3 may not generate voltage surge or overshoot since the drain of the first transistor M1 and the drain of the third transistor M3 are still in the low impedance state.

In this embodiment, the fourth voltage V4 is higher than the third voltage V3 and higher than the breakdown voltage of the third transistor M3, therefore an on-state resistance of the third transistor M3 during the second enable period TE2 is smaller than the on-state resistance of the third transistor M3 during the first delay period TD1 and the second delay period TD2. In addition, the third voltage V3 is lower than the breakdown voltage of the third transistor M3, and the third voltage V3 is higher than a threshold voltage of the third transistor M3. Therefore, during the first delay period TD1 and the second delay period TD2, the voltage of the third switch signal VG3 (that is, the third voltage V3) is between the threshold voltage of the third transistor M3 and the breakdown voltage of the third transistor M3. During the second enable period TE2, the breakdown voltage of the third transistor M3 is between the threshold voltage of the third transistor M3 and the voltage of the third switch signal VG3 (that is, the fourth voltage V4). Therefore, the absolute value of the drain-gate voltage VDG3 of the third transistor M3 remains lower than the absolute value of the breakdown voltage of the third transistor M3.

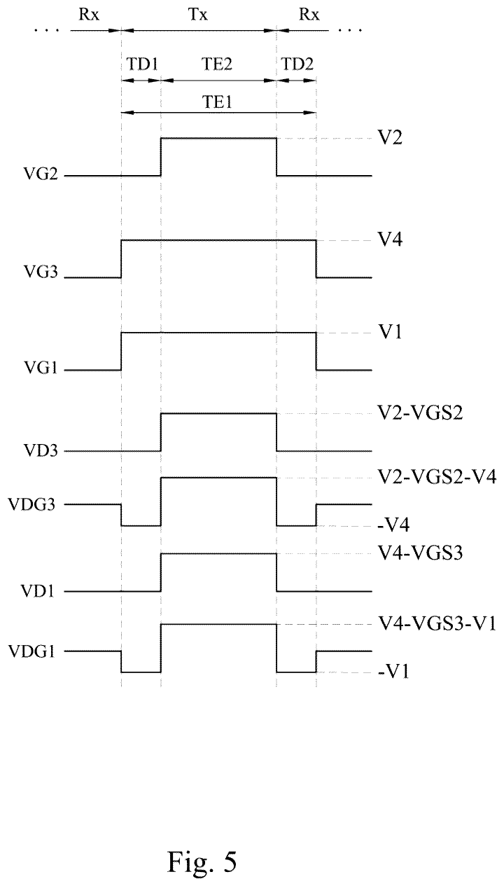

FIG. 5 is a schematic diagram of a signal waveform of a semiconductor device 30 according to an embodiment of this disclosure. The embodiment in FIG. 5 is similar to the embodiment in FIG. 4, so only the differences between the two will be described below. In the embodiment in FIG. 5, when entering the transmitting mode Tx, the third switch signal VG3 is directly switched from the low voltage to the fourth voltage V4 and remains at the fourth voltage V4 during the first enable period TE1. Therefore, the third transistor M3 remains conducted during the first enable period TE1. Then, when the first enable period TE1 is finished, the third switch signal VG3 directly switches from the fourth voltage V4 to the low voltage.

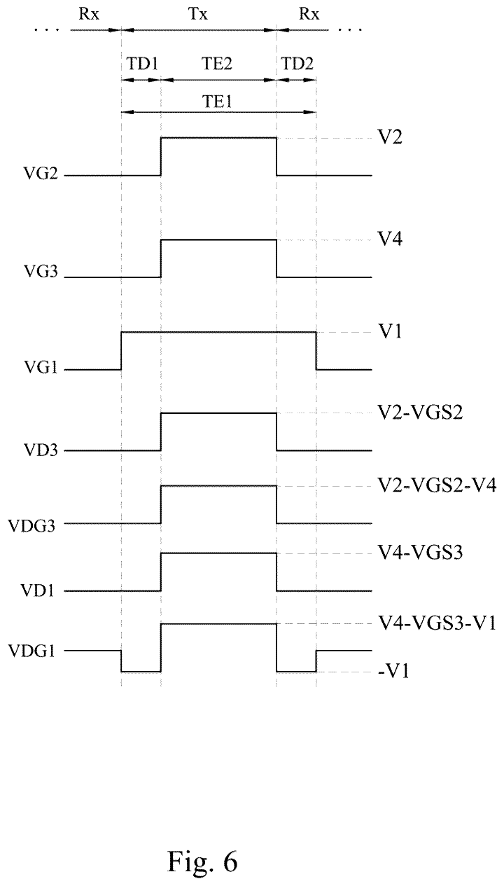

FIG. 6 is a schematic diagram of a signal waveform of the semiconductor device 30 according to an embodiment of this disclosure. The embodiment in FIG. 6 is similar to the embodiment in FIG. 4, so only the differences between the two will be described below. In the embodiment in FIG. 6, the second switch signal VG2 has the low voltage during the first delay period TD1 and the second delay period TD2, and the second switch signal VG2 has a fourth voltage V4 during the second enable period TE2. Therefore, the third transistor M3 is conducted during the second enable period TE2 and is switched off during the first delay period TD1 and the second delay period TD2.

From the above, it could be seen that the third switch signal VG3 may have a simpler waveform or a shorter pulse width. As long as the third transistor M3 is conducted at least during the second enable period TE2, the advantage of preventing surges or overshoots can be implemented.

In addition, although the FIG. 3A mentioned above illustrates that the third transistor M3 may be configured between the first transistor M1 and the second transistor M2, but this disclosure is not limited to this. The semiconductor device 30 is configured with a plurality of series-connected transistors between the first transistor M1 and the second transistor M2. Referring to FIG. 3B, FIG. 3B is a schematic diagram of a semiconductor device 30′ according to another embodiment of this disclosure. As shown in FIG. 3B, the semiconductor device 30′ is configured with the third transistor M3 and a fourth transistor M4 between the first transistor M1 and the second transistor M2. The third transistor M3 and the fourth transistor M4 are coupled in series between the first transistor M1 and the second transistor M2, and the third transistor M3 and the fourth transistor M4 are respectively controlled by the third switch signal VG3 and a fourth switch signal VG4. In an embodiment, the signal waveform of the fourth switch signal VG4 is similar to the signal waveform of the third switch signal VG3 in FIG. 4, FIG. 5 or FIG. 6. Therefore, the third transistor M3 and the fourth transistor M4 have the same or similar operations. For the sake of simplicity, they will not be repeated here. It should be understood that two or more transistors connected in series may be configured between the first transistor M1 and the second transistor M2. The two or more transistors connected in series (e.g., the third transistor M3 and the fourth transistor M4 in FIG. 3B) may be controlled by similar switch signals and may also achieve the functions and operations described in FIG. 3A, FIG. 4 to FIG. 6.

In some embodiments, the second transistor M2 is implemented of an input/output device metal oxide semiconductor (IO MOS for short) or a laterally diffused metal oxide semiconductor (LDMOS for short). Therefore, the breakdown voltage of the second transistor M2 is greater than the breakdown voltage of the first transistor M1, and the breakdown voltage of the second transistor M2 is greater than the breakdown voltage of the third transistor M3 (which the breakdown voltage of the second transistor M2 may also be greater than the breakdown voltage of the fourth transistor M4 in FIG. 3B).

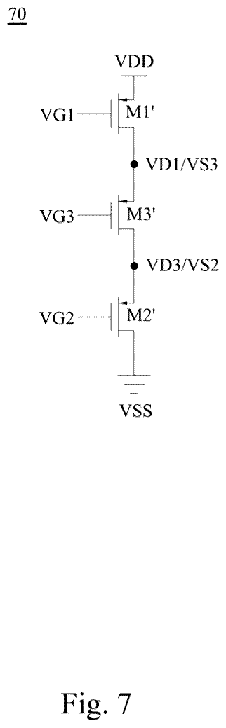

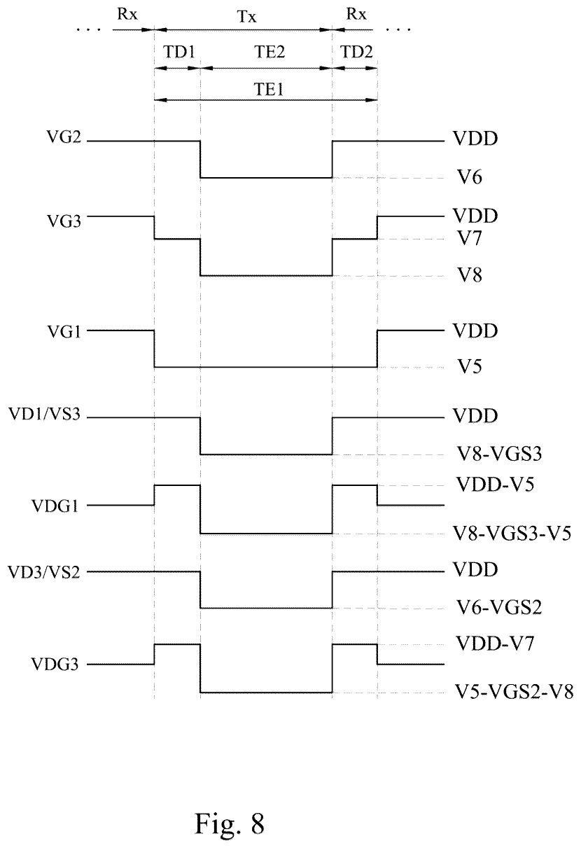

FIG. 7 is a schematic diagram of a semiconductor device 70 according to an embodiment of this disclosure. The semiconductor device 70 in FIG. 7 is similar to the semiconductor device 30 in FIG. 3A, so only the differences between the two will be described below. The semiconductor device 70 includes a first transistor M1′, a second transistor M2′ and a third transistor M3′, wherein the first transistor M1′, the third transistor M3′ and the second transistor M2′ are coupled in series between the power terminal VDD and the power terminal VSS. In some embodiments, the first transistor M1′, the second transistor M2′ and the third transistor M3′ may be implemented of P-type metal-oxide-semiconductor field-effect transistors (PMOSFET for short). In the embodiments in FIG. 7 and FIG. 8, the drain voltage VD1 of the first transistor M1′ is a source voltage VS3 of the third transistor M3′, and a drain voltage VD3 of the third transistor M3′ is a source voltage VS2 of the second transistor M2′.

Referring to FIG. 7 and FIG. 8 at the same time, FIG. 8 is a schematic diagram of a signal waveform of a semiconductor device 70 according to an embodiment of this disclosure. The signal time sequence in FIG. 8 is similar to the content described above in connection with FIG. 4, but the signal waveform of the signal time sequence in FIG. 8 is opposite to the signal waveform in FIG. 4. When entering the transmitting mode Tx, the first switch signal VG1 may drop to a fifth voltage V5 to be conducted the first transistor M1′. The first switch signal VG1 may remain at the fifth voltage V5 during the first enable period TE1, the absolute value of the gate-source voltage VGS1 (not shown in the figure) of the first transistor M1′ is higher than the absolute value of the threshold voltage VTH1 (not shown in the figure) of the first transistor M1′ during the first enable period TE1, that is, |VGS1|=|VG1-VS1|=|V5-VDD|>|V_{TH1}|. The absolute value of the drain-gate voltage VDG1 of the first transistor M1′ is lower than the absolute value of the breakdown voltage V_{BD1} (not shown in the figure) of the first transistor M1′, that is, |VDG1|<|V_{BD1}|. Such as shown in FIG. 8, |VDD-V5|<|V_{BD1}| and |V8-VGS3-V5|<|V_{BD1}|. The second switch signal VG2 has a high voltage (e.g., the voltage of the power terminal VDD) during the first delay period TD1 and the second delay period TD2 to switch off the second transistor M2′, and the second switch signal VG2 decreases to a sixth voltage V6 to be conducted the second transistor M2′ during the second enable period TE2. The third switch signal VG3 may have a seventh voltage V7 to be conducted the third transistor M3′ during the first delay period TD1 and the second delay period TD2. During the first delay period TD1 and the second delay period TD2, the absolute value of the gate-source voltage VGS3 (not shown in the figure) of the third transistor M3′ is higher than the threshold voltage V_{TH3} (not shown in the figure) of the third transistor M3′, that is, |VGS3|=|VG3-VS3|=|V7-VDD|<|V_{TH3}|. The absolute value of the drain-gate voltage VDG3 of the third transistor M3′ is lower than the absolute value of the breakdown voltage V_{BD3} (not shown in the figure) of the third transistor M3′, that is, |VDG3|<|V_{BD3}|. As shown in FIG. 8, that is, |VDD-V7|<|V_{BD3}|.

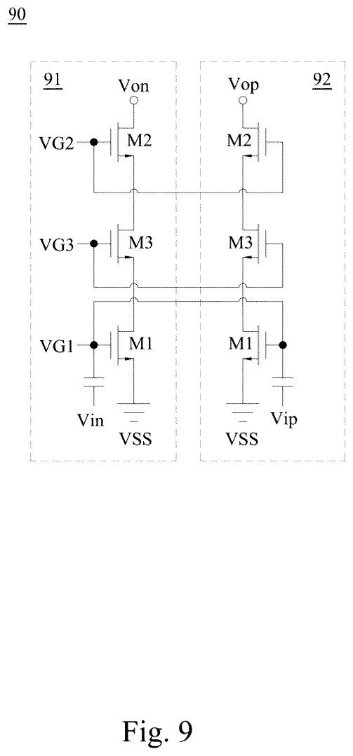

FIG. 9 is a schematic diagram of an amplifier 90 according to an embodiment of this disclosure. An amplifier 90 includes a first semiconductor device 91 and a second semiconductor device 92. Each of the first semiconductor device 91 and the second semiconductor device 92 can be implemented by the semiconductor device 30 in FIG. 3A or the semiconductor device 30′ in FIG. 3B. That is, the first semiconductor device 91 and the second semiconductor device 92 each have the first transistor M1, the second transistor M2 and third transistor M3. The third transistor M3 is coupled between the first transistor M1 and the second transistor M2 (for brief explanation, FIG. 9 only schematically illustrates the third transistor M3 for each semiconductor device, but multiple transistors connected in series, such as the third transistor M3 and the fourth transistor M4 shown in FIG. 3B, can be provided between the first transistor M1 and the second transistor M2 in actual applications). The first semiconductor device 91 and the second semiconductor device 92 are coupled to each other to receive the same first switch signal VG1, the same second switch signal VG2 and the same third switch signal VG3.

The gate of the first transistor M1 of the first semiconductor device 91 is configured to receive a first differential input signal Vin (e.g., an inverted differential input signal), and the drain of the second transistor M2 of the first semiconductor device 91 is configured to generate a first differential output signal Von (e.g., an inverted differential output signal). The gate of the first transistor M1 of the second semiconductor device 92 is configured to receive a second differential input signal Vip (e.g., a non-inverted differential input signal), and the drain of the second transistor M2 of the second semiconductor device 92 is configured to generate a second differential output signal Vop (e.g., a non-inverted differential output signal).

In operation, the first semiconductor device 91 and the second semiconductor device 92 are applicable to the signal waveforms of any of the embodiments shown in FIGS. 4 to 6. Therefore, for each of the first semiconductor device 91 and the second semiconductor device 92, the first transistor M1 is configured to be conducted during the first enable period TE1, the second transistor M2 is configured to be conducted during the second enable period TE2, the third transistor M3 is configured to be conducted at least during the second enable period TE2, wherein the first enable period TE1 includes the first delay period TD1, the second enable period TE2 and the second delay period TD2 arranged in sequence.

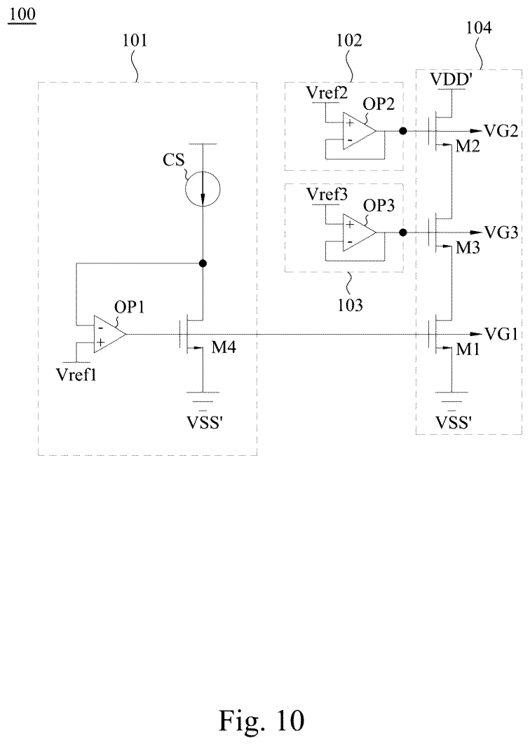

FIG. 10 is a schematic diagram of a biasing circuit 100 according to an embodiment of this disclosure. A biasing circuit 100 includes a first voltage generation circuit 101, a second voltage generation circuit 102, a third voltage generation circuit 103 and a semiconductor device 104. The semiconductor device 104 may be implemented by the semiconductor device 30 in FIG. 3A or the semiconductor device 30′ in FIG. 3B, that is, the semiconductor device 104 includes the first transistor M1, the second transistor M2, and the third transistor M3 (or further including another transistor connected in series with the third transistor M3, seeing fourth transistor M4 in FIG. 3B), and the first transistor M1, the third transistor M3 and the second transistor M2 are sequentially connected in series between a power terminal VSS' and a power terminal VDD'.

In some embodiments, the biasing circuit 100 is coupled to the amplifier 90 in FIG. 9, and the biasing circuit 100 is configured to provide the first switch signal VG1, the second switch signal VG2 and the third switch signal VG3 to the amplifier 90 in FIG. 9. In an embodiment, the magnitudes of a first reference voltage Vref1 and a second reference voltage Vref2 are controlled through an external operating circuit (not shown in the figure), that is, the first switch signal VG1, the second switch signal VG2, and the third switch signal VG3 generated by the biasing circuit 100 have the signal waveforms of any of the embodiments in FIGS. 4 to 6 mentioned above.

The first voltage generation circuit 101 includes a first amplifier OP1, a current source CS and a fourth transistor M4. The inverted input terminal of the first amplifier OP1 is coupled to the current source CS and the drain of the fourth transistor M4 to form an negative feedback. The non-inverted input terminal of the first amplifier OP1 is configured to receive the first reference voltage Vref1. The output terminal of the first amplifier OP1 is configured to output the first switch signal VG1 to the gate of the first transistor M1 and the gate of the fourth transistor M4 of the semiconductor device 104, to control the first transistor M1 of the semiconductor device 104 to be conducted during the first enable period TE1.

The second voltage generation circuit 102 includes a second amplifier OP2. An inverted input terminal and an output terminal of the second amplifier OP2 are coupled to each other to form an negative feedback, and the output terminal of the second amplifier OP2 is configured to generate the second switch signal VG2. In addition, the non-inverted input terminal of the second amplifier OP2 is configured to receive the second reference voltage Vref2. The output terminal of the second amplifier OP2 is configured to output the second switch signal VG2 to the gate of the second transistor M2 of the semiconductor device 104, so that the second amplifier OP2 may control the second transistor M2 of the semiconductor device 104 to be conducted during the second enable period TE2.

The third voltage generating circuit 103 includes a third amplifier OP3. An inverted input terminal of the third amplifier OP3 and its corresponding source of the third transistor M3 are coupled to each other to form an negative feedback, and the output terminal of the third amplifier OP3 is configured to output the third switch signal VG3 to its corresponding third transistor M3. In addition, a non-inverted input terminal of the third amplifier OP3 is configured to receive a third reference voltage Vref3. An output terminal of the third amplifier OP3 is configured to output the third switch signal VG3 to the gate of the third transistor M3 of the semiconductor device 104, so that the third amplifier OP3 may control the third transistor M3 of the semiconductor device 104 to be conducted at least during the second enable period TE2. In an embodiment, in addition to being output to the third transistor M3, the third switch signal VG3 generated by the third voltage generation circuit 103 in FIG. 10 may also be output to another transistor connected in series with the third transistor M3 (e.g., the transistor M4 as shown in FIG. 3B). Or in another embodiment, the biasing circuit 100 may further include a fourth voltage generation circuit (not shown in the figure) for generating the fourth switch signal VG4, the fourth switch signal VG4 is output to the fourth transistor M4 shown in FIG. 3B, wherein the structure of the fourth voltage generation circuit (not shown in the figure) is similar to the third voltage generation circuit 103.

In addition, unless otherwise specified in the specification, any singular term also includes the meaning of the plural form.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the invention. In view of the foregoing, it is intended that the present invention cover modifications and variations of this invention provided they fall within the scope of the following claims.

What is claimed is:

1. A semiconductor device, comprising:
a first transistor, configured to be conducted during a first enable period; and
a second transistor, configured to be conducted during a second enable period, wherein the first transistor and the second transistor are coupled in series,
wherein the first enable period comprises a first delay period, the second enable period and a second delay period arranged in sequence.

2. The semiconductor device of claim 1, further comprising:
a third transistor, wherein the third transistor is coupled between the first transistor and the second transistor,
wherein the third transistor is conducted at least during the second enable period.

3. The semiconductor device of claim 2, wherein the third transistor is conducted during the first enable period,
wherein the third transistor comprises an on-state resistance, the on-state resistance of the third transistor during the second enable period is smaller than the on-state resistance of the third transistor during the first delay period, and the on-state resistance of the third transistor during the second enable period is smaller than the on-state resistance of the third transistor during the second delay period.

4. The semiconductor device of claim 3, wherein the third transistor is controlled by a switch signal and the third transistor has a threshold voltage and a breakdown voltage,
wherein during the first delay period and the second delay period, a voltage of the switch signal is between the threshold voltage and the breakdown voltage,
wherein during the second enable period, the breakdown voltage is between the threshold voltage and the voltage of the switch signal.

5. The semiconductor device of claim 2, wherein the third transistor remains being conducted during the first enable period.

6. The semiconductor device of claim 2, wherein the third transistor is conducted during the second enable period, and the third transistor is switched off during the first delay period and the second delay period.

7. The semiconductor device of claim 2, wherein a breakdown voltage of the second transistor is greater than a breakdown voltage of the first transistor, and the breakdown voltage of the second transistor is greater than a breakdown voltage of the third transistor.

8. The semiconductor device of claim 2, further comprising a fourth transistor, wherein the third transistor and the fourth transistor are coupled in series between the first transistor and the second transistor.

9. The semiconductor device of claim 2, wherein the first transistor, the second transistor and the third transistor are all P-type transistors or all N-type transistors.

10. An amplifier, comprising:
a first semiconductor device; and
a second semiconductor device, coupled to the first semiconductor device,
wherein the first semiconductor device and the second semiconductor device each comprises:
a first transistor, configured to be conducted during a first enable period;
a second transistor, configured to be conducted during a second enable period; and
a third transistor, wherein the third transistor is coupled between the first transistor and the second transistor,
wherein the first transistor is configured to receive an input signal, and the second transistor is configured to generate an output signal,
wherein the first enable period comprises a first delay period, the second enable period and a second delay period arranged in sequence, wherein the third transistor is conducted at least during the second enable period.

11. The amplifier of claim 10, wherein the third transistor is conducted during the first enable period,
wherein the third transistor comprises an on-state resistance, and the on-state resistance of the third transistor during the second enable period is smaller than the on-state resistance of the third transistor during the first delay period, and the on-state resistance of the third transistor during the second enable period is smaller than the on-state resistance of the third transistor during the second delay period.

12. The amplifier of claim 11, wherein the third transistor is controlled by a switch signal and has a threshold voltage and a breakdown voltage,
wherein during the first delay period and the second delay period, a voltage of the switch signal is between the threshold voltage and the breakdown voltage,
wherein during the second enable period, the breakdown voltage is between the threshold voltage and the voltage of the switch signal.

13. The amplifier of claim 10, wherein the third transistor remains being conducted during the first enable period.

14. The amplifier of claim 10, wherein the third transistor is conducted during the second enable period, and the third transistor is switched off during the first delay period and the second delay period.

15. The amplifier of claim 10, further comprising a fourth transistor, wherein the third transistor and the fourth transistor are coupled in series between the first transistor and the second transistor.

16. A biasing circuit, comprising:
a semiconductor device, comprising a first transistor, a second transistor and a third transistor, wherein the third transistor is coupled between the first transistor and the second transistor;
a first voltage generation circuit, configured to output a first switch signal to control the first transistor to be conducted during a first enable period;
a second voltage generation circuit, configured to output a second switch signal to control the second transistor to be conducted during a second enable period; and
a third voltage generation circuit, configured to output a third switch signal to control the third transistor to be conducted at least during the second enable period, wherein the third voltage generation circuit and the third transistor form an negative feedback,
wherein the first enable period comprises a first delay period, the second enable period and a second delay period arranged in sequence.

17. The biasing circuit of claim 16, wherein the third transistor is conducted during the first enable period,
wherein the third transistor comprises an on-state resistance, and the on-state resistance of the third transistor during the second enable period is smaller than the on-state resistance of the third transistor during the first delay period, and the on-state resistance of the third transistor during the second enable period is smaller than the on-state resistance of the third transistor during the second delay period.

18. The biasing circuit of claim 17, wherein the third transistor has a threshold voltage and a breakdown voltage, and is controlled by the third switch signal,
wherein during the first delay period and the second delay period, a voltage of the third switch signal is between the threshold voltage and the breakdown voltage,
wherein during the second enable period, the breakdown voltage is between the threshold voltage and the voltage of the third switch signal.

19. The biasing circuit of claim 16, wherein the third transistor remains being conducted during the first enable period.

20. The biasing circuit of claim 16, wherein the third transistor is conducted during the second enable period, and the third transistor is switched off during the first delay period and the second delay period.
